(19) United States
(12) Patent Application Publication
(10) Pub. No.: US 2016/0066483 A1
(43) Pub. Date: Mar. 3, 2016

(54) WIRE HARNESS SHIELD STRUCTURE

(71) Applicant: SUMITOMO WIRING SYSTEMS, LTD., Mie (JP)

(72) Inventors: Minoru FUKUDA, Mie (JP); Masataka WAKABAYASHI, Mie (JP)

(73) Assignee: SUMITOMO WIRING SYSTEMS, LTD., Mie (JP)

(21) Appl. No.: 14/819,619

(22) Filed: Aug. 6, 2015

(30) Foreign Application Priority Data
Aug. 27, 2014 (JP) 2014-172736

(51) Int. Cl. H05K 9/00; H02G 3/04; B60R 16/02

(52) U.S. Cl. CPC H05K 9/0098; B60R 16/0215; H02G 3/0481

(57) ABSTRACT

A wire harness shield structure that can exhibit a required shield effect while sufficiently meeting demands for weight reduction and cost mitigation is provided. The wire harness shield structure includes: an exterior member that encloses an electrical line group so as to hold the electrical line group in a bundled manner, the electrical line group being constituted by a plurality of electrical lines; a shield material that encloses a predetermined section of the electrical line group that is to be shielded; and a ground connection member that grounds the shield member. A heat shrink tube that holds the electrical line group in the bundled manner constitutes the exterior member, and the shield material is constituted by a metal thin-film that is formed to attach to an inner circumferential surface portion of the heat shrink tube.

### TECHNICAL FIELD

The present invention relates to a wire harness shield structure, and in particular relates to a wire harness shield structure that shields a predetermined routing section of an electrical line group.

### BACKGROUND ART

Conventionally, in the case of shielding (electrostatic shielding and/or electromagnetic shielding) an electrical line group of a wire harness in a predetermined routing section, a shield structure has often been implemented in which the electrical line group in the section to be shielded is enveloped with a shield material such as a braided shield material, a served shield material, or an aluminum foil shield material, and then enclosed with an exterior member that has insulating properties (e.g., see JP H10-125138A and JP 2009-93934A).

Also, there are known to be shield structures in which a shield layer made up of a metal thin film is integrally formed on an exterior member such as a corrugated tube so as to provide the effects of mechanical protection and electromagnetic shielding for the electrical line group of the wire harness. (e.g., see JP H9-191409A JP 2008-282745A, and JP S60-1336970. JP H10-125138A, JP 2009-93934A, JP H9-191409A, JP 2008-282745A, and JP 560-133697U are examples of related art.

### SUMMARY OF THE INVENTION

However, with the shield structure of the former conventional wire harness in which the electrical line group is enveloped by a shield material and an exterior member, the shield material and the exterior member are wrapped in layers around the electrical line bundle in the routing section to be shielded, and therefore the task of wrapping was time consuming. Moreover, the wire harness bulges, and the demands for cost mitigation and weight reduction for the wire harness could not be sufficiently met. Also, this issue becomes prominent in the case of a routing path section to be shielded over a wide range.

Particularly, in the case in which the electrical line group has an intermediate splice for purposes such as grounding or multipoint connection, the conductor exposed portion where the sheathing has been stripped from the intermediate splice portion has insulating tape wrapped around it, or is covered with a heat shrink tube, and furthermore the conductor exposed portion is enveloped from the outside with a shield material, and enclosed by an exterior member, thus becoming a multi-layer structure. For this reason, in addition to the task of wrapping being time consuming, the wire harness bulges, and the above issue becomes even more prominent.

On the other hand, with the latter conventional wire harness shield structures in which a shield layer made up of a metal film is formed integrally on an exterior member such as a corrugated tube, depending on the thickness of the electrical line group in a bundled form, there was a need to either prepare various types of exterior members that had a suitable inner diameter, or use an exterior member with a diameter larger than necessary. For this reason, even in this wire harness shield structure, demands for cost mitigation and weight reduction of the wire harness could not be sufficiently met.

The present invention has been achieved in light of the above-described conventional problems, and an object thereof is to provide a wire harness shield structure that can exhibit the required shield effects, and sufficiently meet demands for cost mitigation and weight reduction.

In order to achieve the above object, a wire harness shield structure according to the present invention includes: an exterior member that encloses an electrical line group so as to hold the electrical line group in a bundled manner, the electrical line group being constituted by a plurality of electrical lines; a shield material that encloses a predetermined section of the electrical line group that is to be shielded; and a ground connection member that grounds the shield member, wherein a heat shrink tube that holds the electrical line group in the bundled manner constitutes a principal portion of the exterior member, the exterior member has a metal thin-film formed so as to be attached to a surface portion of the heat shrink tube, and the shield material is constituted by the metal thin-film.

According to this configuration, in the present invention, the task of wrapping an exterior member and a shield material in layers around the electrical line group is not needed, and there are no cases of the wire harness bulging. Also, because a heat shrink tube is used, there is no need to prepare various types of exterior members according to the thickness of the electrical line group in a bundled form, nor is there a need to use an exterior member that has a diameter larger than necessary. Thus, the shield structure can sufficiently meet demands for cost mitigation and weight reduction for the wire harness.

In the wire harness shield structure of the present invention, a metal-containing plasma polymerization layer may be formed on an attachment surface portion of the heat shrink tube and the metal thin-film, and it is preferable that the metal thin-film is a vapor deposition film formed by RF ion plating.

According to this configuration, a metal-containing plasma polymerization layer, in which the metal thin-film and the heat shrink tube penetrate each other so as to be bonded at the molecular level, is formed in the attachment surface portion between the metal thin-film and the heat shrink tube, and a shield layer that can shrink along with the heat shrinking of the heat shrink tube is formed in the attachment surface portion. The metal-containing plasma polymerization film layer, in other words the metal-containing plasma polymerization layer described here can be favorably formed using RF ion plating, but if sufficient attaching strength (peel resistance) against heat shrinkage can be provided, the film may be formed with a different method, such as sputtering.

In the wire harness shield structure of the present invention, at least a portion of the metal thin-film may be formed on an outer circumferential surface portion of the heat shrink tube, the ground connection member may have a first junction portion that is in a form of a cable tie and encloses the heat shrink tube while being in contact with the metal thin-film, and a second junction portion that is in a form of an anchor hook and is capable of locking the first junction portion to an opening edge portion of a metal panel, and a conductor for grounding that is formed on each of the first junction portion and the second junction portion may be constituted so as to include a vapor deposition film that is formed by RF ion plating.

According to this configuration, a conductor film for grounding that is firmly attached to the surface of the ground connection member in the form of a band clip is formed, the shield material can be grounded at the same time as when a bundle of electrical lines that have had the heat shrink tube placed over them is fixed to a vehicle body panel or the like, and the shield structure is further effective with respect to cost mitigation and weight reduction. Also, in this case, a conductor film that does not easily peel can be formed on the surface of a light-weight and comparatively flexible band clip body that is formed by resin or the like, and therefore a more stable state of contact between the conductor film for grounding and the metal thin-film that constitutes the shield material can be ensured, and the metal thin-film for shielding and the conductor film for grounding are each not likely to become damaged.

According to the present invention, a wire harness shield structure that can exhibit the required shield effects, and sufficiently meet demands for cost mitigation and weight reduction can be provided.

### BRIEF DESCRIPTION OF THE DRAWINGS

FIG. 1 is a side view of the principal portions of a wire harness having a wire harness shield structure according to a first embodiment of the present invention;

FIG. 2 is a cross-section viewed along arrows II-II in FIG. 1;

FIG. 3 is an illustrative drawing of a sheathing task process in which insulating tape or the like is wrapped around a splice portion of an electrical line group included in the wire harness shown in FIG. 1;

FIG. 4 is an illustrative drawing of a task process in which the electrical lines that have been through the intermediate splice portion sheathing task shown in FIG. 3, and other electrical lines and a drain line are enclosed by a heat shrink tube that has a metal thin-film for shielding on the inner circumferential side, and then the heat shrink tube is shrunk with heat;

FIG. 5 is a side view of the principal portions of a wire harness having a wire harness shield structure according to a second embodiment of the present invention;

FIG. 6 is a partially enlarged view of the vicinity of a band clip-shaped ground connection member of the wire harness shown in FIG. 5;

FIG. 7 is a cross-section viewed along arrows VII-VII in FIG. 5; and

FIG. 8 is a transverse cross-sectional view showing a variation of an exterior member in a wire harness that has a wire harness shield structure according to the second embodiment of the present invention.

### EMBODIMENTS OF THE INVENTION

The following describes embodiments of the present invention with reference to the drawings.

### First Embodiment

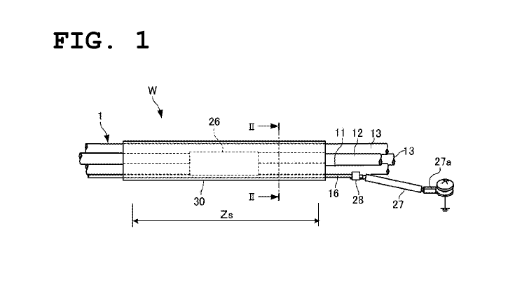

FIGS. 1 to 4 show an electrical line group 1 of a wire harness W that has a wire harness shield structure according a first embodiment of the present invention.

Note that the wire harness W of the present embodiment is a unit in which multiple connection terminals and connectors or the like, not shown in the drawing, are attached to the bundled electrical line group 1, and is configured so that electronic devices that are equipped in a vehicle can be connected to a power source or control equipment, for example.

The electrical line group 1 of the wire harness W has flexibility so that it can be routed along a predetermined routing path on a vehicle body panel, which is not illustrated, and a shield section Zs which requires a shield for electrostatic shielding or the like is provided in a midway portion of the routing path. Note that shields, such as the electrostatic shield described here, include an electrostatic shield, and other shield shields, such as an electromagnetic shield, can also be included.

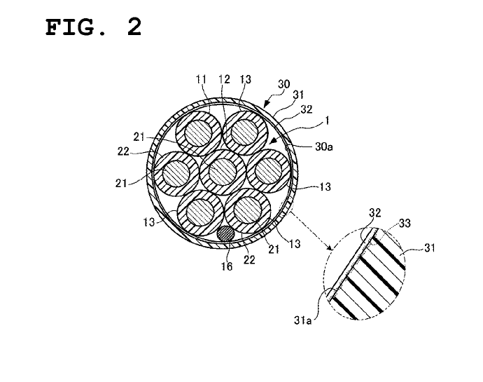

As shown in FIG. 1 and FIG. 2, the electrical line group 1 (multiple electrical lines) includes a first electrical line 11, a second electrical line 12, third electrical lines 13, and a drain line 16.

The electrical lines 11 to 13 each have a conductor 21 at their center and a cylindrical sheathing 22 that surrounds the conductor 21, and the conductor 21 is constituted by multiple individual annealed copper wires (a soft conductor line) or the like, that are twisted together into a circular stranded line. Of course, the conductor 21 may be constituted by a single-core line instead of a stranded line. The sheathing 22 is constituted by an insulating material that is cylindrical, and is made of resin in which the main constituent is a material such as polyethylene or vinyl chloride, for example. The drain line 16 is an electrical line that is only made up of a conductor or the like, and is an electrical line without insulating sheathing in at least the shield section Zs.

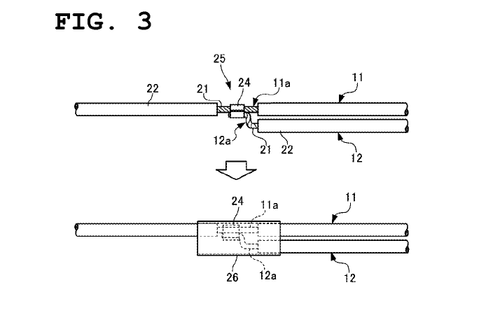

As shown in FIG. 3, the first electrical line 11 has an exposed conductor portion 11a, in which the sheathing 22 is stripped to expose an intermediate portion of the conductor 21, in a predetermined section in the length direction for which shielding is required, that is to say the shield section Zs. Also, a conductor exposed portion 12a, in which one end portion of the conductor 21 of the second electrical line 12 is exposed, is connected to the conductor exposed portion 11a of the first electrical line 11 with a crimped terminal 24 or the like so as to be electrically conductive.

The intermediate conductor exposed portion 11a of the first electrical line 11 along with the conductor exposed portion 12a and the crimped terminal 24 on one end side of the conductor exposed portion 12a constitute an intermediate splice portion 25 that forms a multipoint connection from the first electrical line 11 to the second electrical line 12.

A cylindrical insulating sheathing 26 is attached to this intermediate splice portion 25, the cylindrical insulating sheathing 26 being obtained by, for example, wrapping insulating tape (not shown in the drawings) so as to enclose the entire range of the conductor exposed portions 11a and 12a.

The third electrical line 13 does not have a conductor exposed portion like the intermediate splice portion 25 inside the shield section Zs, and in the present embodiment, the third electrical line 13 refers to all electrical lines, excluding the first electrical line 11 and the second electrical line 12 that constitute the intermediate splice portion 25, and the drain line 16, which are inward of the exterior member 30.

Note that the wire harness W may be configured such that it does not include the third electrical line 13. Also, in the case in which multiple third electrical lines 13 are included, the wire harness W may be in a configuration that does not include the first electrical line 11 and the second electrical line 12 (the intermediate splice portion 25 constituted by them). Furthermore, the electrical line 13 may have a cylindrical conductor that is between the inner and outer sheathing layers or a shield metal layer that encloses the conductor.

The exterior member 30 that has heat shrinking properties is attached in a heat shrunk state to the electrical line group 1 that includes the first to the third electrical lines 11 to 13 so as to enclose the electrical line group 1 in the shield section Zs, and the electrical line group 1 is held in a state in which the electrical line group 1 is bound into a single bundled state by the exterior member 30.

Also, the drain line 16 is set with a transverse cross-sectional shape and an outer diameter that can come into contact with an inner circumferential surface 30a (see FIG. 2) of the exterior member 30 with a predetermined contact pressure between any of the adjacent electrical lines 11 to 13 and the exterior member 30 after heat shrinking.

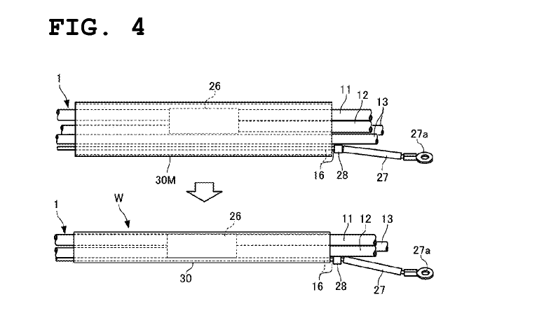

As shown in FIG. 1 and FIG. 4, the drain line 16 is connected to a vehicle body panel or the ground junction portion of an on-board unit (a ground connection including the earth) via an extension joint 28 and an earth lead 27 to which a circular grounding terminal 27a or the like is attached.

Also, a cylindrical shield material (described later in detail) that encloses the shield section Zs of the electrical line group 1 is mounted integrally in the form of a film to an inner circumferential surface 30a side of the exterior member 30 that comes into contact with the drain line 16, and the drain line 16 is a ground connection member for grounding the shield material.

Specifically, as shown in FIG. 2, a cylindrical heat shrink tube 31 that holds the electrical line group 1 in the bundled manner constitutes a principal portion of the exterior member 30, and a cylindrical metal thin-film 32 that is formed so as to attach to an inner circumferential surface portion 31a (a surface portion) of the heat shrink tube 31 is integrally provided in the exterior member 30, and constitutes the above shield material.

More specifically, similarly to heat shrink tubes that are widely known, the heat shrink tube 31 of the exterior member 30 is mostly formed with a resin such as polyolefin, polyester, polyvinyl chloride, or polytetrafluoroethylene, and has heat shrinking capabilities in which the inner diameter can shrink to 50 to 70% of the inner diameter of the heat shrink tube prior to heat shrinking.

The metal thin-film 32 for shielding that is formed on the exterior member 30 is a vapor deposited film formed by RF ion plating, which is a type of physical vapor deposition, and is a thin-film that is constituted by aluminum (Al) or an aluminum alloy, or copper (Cu) or a copper alloy, which is favorable for electrostatic shields, etc. Note that according to the configuration of the electrical line group 1 and the demanded characteristics, it is conceivable for the metal thin-film 32 of the heat shrinking exterior member 30 to be configured having a shield layer made up of another metal such as an iron or an iron-based metal that are favorable for electromagnetic shielding.

The RF ion plating described here is executed by, for example, using multiple vacuum chambers, which are connected in the feed direction of the work piece that is the material for the heat shrink tube 31, and placing a vapor deposition metal material (hereinafter referred to as “vapor deposition metal material”) and the work piece in a later-stage chamber equipped with an electron gun and a high-frequency induction coil.

Specifically, first, the interior of an early-stage vacuum chamber is evacuated to a high vacuum of approximately 10⁻³ to 10⁻⁴ Pa, and the interior of the connected later-stage chamber is vacuumed to a higher vacuum than the early-stage vacuum (e.g., an extreme high vacuum of 10⁻⁸ Pa or higher) using a vacuum pump for very high or extreme high vacuum. Also, an inactive gas or a reactive gas is injected into the later-stage chamber at the same time as the vacuuming.

Then, by applying a high-frequency current to the induction coil in the later-stage chamber that is in an ultra-high vacuum state, low-temperature plasma, which is obtained by separation (dissociation) into ions and electrons by the high-frequency electromagnetic field, is inductively generated, and the metal vapor deposition material is irradiated with an electron beam so as to vaporize the metal while negatively biasing the material of the heat shrink tube that is an insulating material.

At this time, the metal particles become plus ions and are accelerated toward the workpiece side, and in the case where a reactive gas is injected into the chamber, the bonding chemical reaction between the metal particles and the reactive gas is promoted. Furthermore, the ionized vapor metal atoms and the like in the plasma are accelerated by the cathode dark space appearing in the vicinity of the workpiece, and collide with the surface of the workpiece with high energy. Accordingly, the surface portion of the workpiece is heated at the molecular level, and a metal vapor deposition film with firm adhesion is formed.

The workpiece with the metal vapor deposition film formed thereon in this way becomes the exterior member 30 formed such that the metal thin-film 32 is attached to at least the inner circumferential surface of the heat shrink tube 31. Also, a metal-containing plasma polymerization film layer (i.e., the metal-containing plasma polymerization layer 33), which is a firm attachment layer in which the heat shrink tube 31 and the metal thin-film 32 of the exterior member 30 penetrate each other so as to be bonded at the molecular level, is formed in the attachment surface portion between the heat shrink tube 31 and the metal thin-film 32.

Note that the metal-containing plasma polymerization film layer referred to here, that is to say the metal-containing plasma polymerization layer, can be favorably formed by RF ion plating, but as long as it is possible to provide sufficient attachment strength (peeling resistance) against heat shrinking, it may be formed by another method such as sputtering.

The metal thin-film 32 formed so as to be attached to the heat shrink tube 31 of the exterior member 30 in this way is an approximately tubular film that is not likely to detach and penetrates into the heat shrink tube 31 at the molecular level in the metal-containing plasma polymerization layer 33 portion, and is set with a film thickness value that is low to the extent of surface roughness of the heat shrink tube 31, for example from a minimum film thickness value of 1 μm or lower to several tens of μm. Also, during heat shrinking of the exterior member 30, it can undergo heat shrinking integrally with the inner circumferential surface portion 31a of the heat shrink tube 31, and it can change in shape so as to have a substantially larger film thickness and density than during film formation.

Next is a description of actions.

In the present embodiment configured as described above, as shown in. 3, the conductor exposed portion 12a on the one end side of the second electrical line 12 is connected to the intermediate conductor exposed portion 11a of the first electrical line 11 in advance using the crimped terminal 24, and the intermediate splice portion 25 is formed. Then, the first and second electrical lines 11 and 12 forming the intermediate splice portion 25, the third electrical lines 13, and the drain line 16 are inserted into a un-shrunk exterior member 30M in the state before heat shrinking of the exterior member 30, as shown in FIG. 4.

Next, the un-shrunk exterior member 30M is heated with a predetermined heating temperature and heating timing using a heating means such as a dryer, and the inner diameter is shrunk to 50 to 75% of the pre-shrinking diameter so as to hold the electrical line group 1 in one bundle, and thus the exterior member 30 comes into close contact with the outer circumference of the electrical line group 1.

At this time, the drain line 16 and the metal thin-film 32 of the exterior member 30 are in close contact over the entire range in the length direction of the exterior member 30, and grounding via the grounding lead line 27 or the like is possible.

In the present embodiment in which the intermediate splice portion 25 is sheathed, and the electrical line group 1 is held in a bundled manner by the exterior member 30 through this task procedure, there is no need to wrap the shield material and the exterior member in layers around the electrical line group 1 as in conventional technology, the task of attaching a shield to the electrical line group 1 can be significantly facilitated, and the wire harness W is not likely to be bulky.

Moreover, due to using the heat shrinking exterior member 30 whose main component is the heat shrink tube 31, there is no need to prepare various types of exterior members according to the thickness of the bundled electrical line group 1, nor is there a need to use an exterior member with a larger diameter than necessary.

Accordingly, the shield structure can sufficiently meet demands for weight reduction and cost mitigation for the wire harness W as well.

Also, in the present embodiment, a firm attachment layer in which the heat shrink tube 31 and the metal thin-film 32 penetrate each other and are bonded at the molecular level is formed in the metal-containing plasma polymerization layer 33, which is the attachment surface portion between the heat shrink tube 31 and the metal thin-film 32, and the metal thin-film 32 is a thin film with a thickness lower than the surface roughness of the heat shrink tube 31, and therefore the metal thin-film 32 can shrink along with heat shrinking of the heat shrink tube 31.

Moreover, in the present embodiment, the metal thin-film 32 of the exterior member 30 is a vapor deposition film formed by RF ion plating, the adhesion and throwing power of the metal thin-film 32 on the inner circumferential surface portion 31a of the heat shrink tube 31 are high, and the fine shielding metal thin-film 32 that is not likely to detach can be reliably formed in the necessary shield section Zs. Note that the throwing power referred to here is the ease with which the vapor deposition film spreads to a non-vapor deposition portion, and specifically corresponds to the magnitude of the ion incidence angle range for film formation with respect to the vapor deposition target surface.

Additionally, when the heat shrink tube 31 shrinks, the metal thin-film 32 shrinks integrally with the inner circumferential surface portion 31a of the heat shrink tube 31, and undergoes deformation such that the film thickness and density thereof substantially increase.

Accordingly, in the present embodiment, it is possible to provide a wire harness shield structure that can exhibit required shield effects while sufficiently meeting demands for weight reduction and cost mitigation.

### Second Embodiment

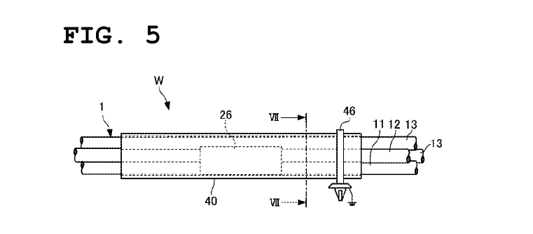

FIGS. 5 to 7 show an electrical line group 1 in a wire harness W that has a wire harness shield structure according to a second embodiment of the present invention. Note that the configuration itself of the electrical lines 11 to 13 of the electrical line group 1 according to the present embodiment is similar to the first embodiment, and the exterior member, the ground connection member and aspect differ from those of the first embodiment. Accordingly, configurations similar to or the same as those in the first embodiment are described using the corresponding constituent element symbols shown in FIGS. 1 to 4, and points of difference with the first embodiment are described below.

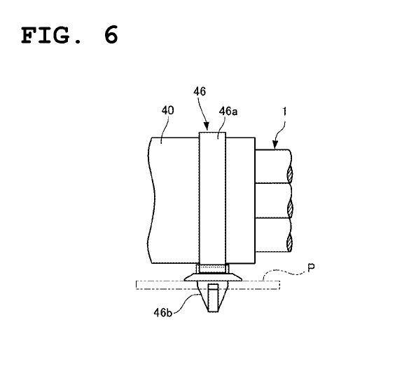

As shown in FIG. 5 and FIG. 6, in the wire harness W of the present embodiment, instead of the exterior member 30 in the first embodiment, an exterior member 40 is provided, and instead of the drain line 16, a ground connection member 46 in the form of a band clip is provided.

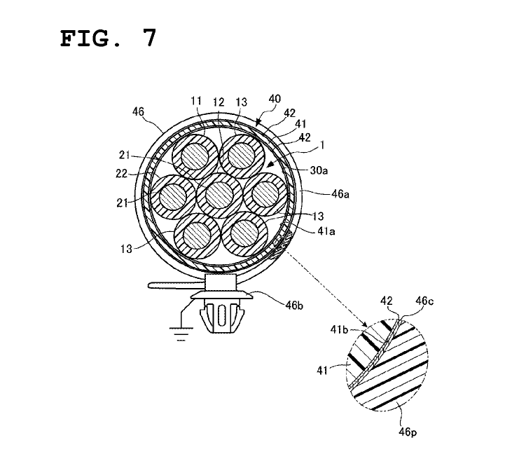

As shown in FIG. 7, a tubular heat shrink tube 41 that holds the electrical line group 1 in a bundled manner constitutes a principal portion of the exterior member 40, and a metal thin-film 42 is provided as a shield material integral with the heat shrink tube 41, so as to attach to at least the outer circumferential surface portion 41b of the heat shrink tube 41.

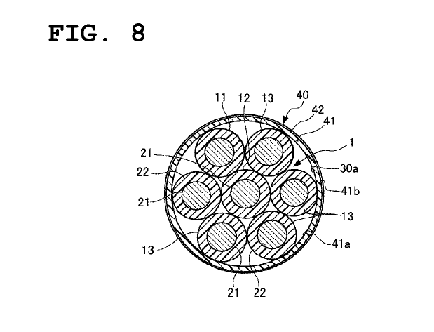

The manufacturing method and materials of the exterior member 40 are similar to the case of the exterior member 30 of the first embodiment, and the metal thin-film 42 is formed on both the inner circumferential surface portion 41a of the heat shrink tube 41 and the outer circumferential surface portion 41b, as shown in FIG. 7 for example. Of course, as shown in FIG. 8, the metal thin-film 42 of the exterior member 40 may be formed so as to be only on the outer circumferential surface portion 41b of the heat shrink tube 41.

On the other hand, as shown in FIG. 6, a ground connection member 46 in the form of a band clip has a first junction portion 46a that is in the form of a band clip and encloses the heat shrink tube 41 while being in contact with the metal thin-film 42 of the exterior member 40, and a second junction portion 46b that is in the form of an anchor hook and is capable of locking the first junction portion 46a to an opening edge portion of the metal panel P on a vehicle body panel, or the like.

Also, as shown by the partial enlargement of the first junction portion 46a in FIG. 7, a conductor film 46c (conductor) for grounding is formed on the first junction portion 46a and the second junction portion 46b so as to cover the surface of resin portions 46p of the first junction portion 46a and the second junction portion 46b. Also, the conductor films 46c for grounding include vapor deposition films that are each formed by RF ion plating.

The method for forming the conductor films 46c for grounding is approximately the same as the method for forming the metal thin-film 32 of the exterior member 30 of the first embodiment, but the film thickness may be larger than the metal thin-film 42, for example.

In the present embodiment as well, a wire harness shield structure that can exhibit the necessary shield effects, and sufficiently meets the demands of cost mitigation and weight reduction can be provided.

Also, in the present embodiment, at least a portion of the metal thin-film 42 of the exterior member 40 is formed on the outer circumferential surface portion 41b of the heat shrink tube 41, while on the other hand, the conductor film 46c for grounding is formed by RF ion plating on both the first junction portion 46a and the section junction portion 46b of the ground connection member 46 in the form of band clip.

Accordingly, the conductor film 46c for grounding that is firmly attached to the surface of the ground connection member 46 in the form of a band clip is formed, the shield material can be grounded at the same time as when the electrical line group 1 in a bundled manner that have had the heat shrink tube 41 placed over them is fixed to a metal panel P of a vehicle body or the like, and the shield structure is further effective with respect to cost mitigation and weight reduction.

Furthermore, the conductor film 46c that does not easily peel can be formed on the surface of the resin portion 46p of the ground connection portion 46 in the form of a band clip that is formed by resin and is light-weight and comparatively flexible, and therefore a more stable state of contact between the conductor film 46c for grounding and the metal thin-film 42 of the exterior member 40 that constitutes the shield material 40 can be ensured, and the metal thin-film 42 for shielding and the conductor film 46c for grounding are each not likely to become damaged.

Note that in the above embodiments, the metal thin-films 32 and 42 for shielding and the conductor film 46c for grounding are formed by RF ion plating with high adhesiveness, but the films may be a vapor deposited film that is formed with another method such as sputtering, and it is also conceivable to form metal thin-films, other than vapor deposited films, that are highly firmly attached, and are formed by a combination of the processing of surface reforming and roughening of the surface or the like, due to low temperature plasma polymerization of a surface portion of the heat shrink tube 31, 41. Also, in the second embodiment, a ground connection member other than the drain line was illustrated in the form of a band clip as an example, however the ground connection member is not particularly limited to this form, and may be a clamp member in the form of a band that is fastened with a screw or the like. Also, it is conceivable to join the ground connection member so that it is in contact with another conductive part supported on the vehicle body side at a predetermined contact pressure, with merely a band portion, and without having an anchor portion.

As described above, the present embodiment can provide a wire harness shield structure that can exhibit the required shield effects, and sufficiently meet demands for cost mitigation and weight reduction, and the present invention is generally useful to wire harness shield structures that shield a predetermined routing section of a group of electrical lines.

### LIST OF REFERENCE NUMERALS

1 Electrical line group
11 Electrical line (first electrical line)
11a Conductor exposed portion (intermediate conductor exposed portion)
12 Electrical line (second electrical line)
12a Conductor exposed portion (conductor exposed portion on one end side)
13 Electrical line (third electrical line)
16 Drain line (ground junction member)
21 Conductor
22 Sheathing (insulating sheathing)
24 Crimped terminal
25 Intermediate splice portion
26 Cylindrical insulating sheathing
27 Grounding lead line
27a Grounding terminal
28 Extension joint
28 Exterior member
30M Un-shrunk exterior member
30a Inner circumferential surface
31 Heat shrink tube
31a Inner circumferential surface portion (surface portion)
32, 42 Metal thin-film
33 Metal-containing plasma polymerization layer (a layer of a plasma polymerization film containing metal)
40 Exterior member
41 Heat shrink tube
41b Outer circumferential surface portion
46 Ground junction portion
46a First junction portion
46b Second junction portion
46c Conductor film
46p Resin portion
Zs Shield section (predetermined section to be shielded)

What is claimed is:

1. A wire harness shield structure comprising:
an exterior member that encloses an electrical line group so as to hold the electrical line group in a bundle, the electrical line group including a plurality of electrical lines;
a shield material that encloses a predetermined section of the electrical line group that is to be shielded; and
a ground connection member that grounds the shield member,
wherein the exterior member includes a heat shrink tube that holds the electrical line group in the bundle, and the shield material includes a metal thin-film formed so as to be attached to a surface portion of the heat shrink tube.

2. The wire harness shield structure according to claim 1, wherein a metal-containing plasma polymerization layer is formed between the heat shrink tube and the metal thin-film.

3. The wire harness shield structure according to claim 2, wherein the metal thin-film is a vapor deposition film formed by RF ion plating.

4. The wire harness shield structure according to claim 1,
wherein at least a portion of the metal thin-film is formed on an outer circumferential surface portion of the heat shrink tube, and
the ground connection member includes a first junction portion that is a cable tie that encloses the heat shrink tube while being in contact with the metal thin-film, a second junction portion that is an anchor hook configured to lock the first junction portion to an opening edge portion of a metal panel, and a conductor for grounding that is formed on each of the first junction portion and the second junction portion including a vapor deposition film that is formed by RF ion plating.

5. The wire harness shield structure according to claim 2,
wherein at least a portion of the metal thin-film is formed on an outer circumferential surface portion of the heat shrink tube, and
the ground connection member includes a first junction portion that is a cable tie that encloses the heat shrink tube while being in contact with the metal thin-film, a second junction portion that is an anchor hook configured to lock the first junction portion to an opening edge portion of a metal panel, and a conductor for grounding that is formed on each of the first junction portion and the second junction portion including a vapor deposition film that is formed by RF ion plating.

6. The wire harness shield structure according to claim 3,
wherein at least a portion of the metal thin-film is formed on an outer circumferential surface portion of the heat shrink tube, and
the ground connection member includes a first junction portion that is a cable tie that encloses the heat shrink tube while being in contact with the metal thin-film, a second junction portion that is an anchor hook configured to lock the first junction portion to an opening edge portion of a metal panel, and a conductor for grounding that is formed on each of the first junction portion and the second junction portion including a vapor deposition film that is formed by RF ion plating.
